(19) United States
(12) Patent Application Publication
(10) Pub. No.: US 2021/0066530 A1
(43) Pub. Date: Mar. 4, 2021

(54) MANUFACTURING METHOD OF SOLAR CELL MODULE

(71) Applicant: Panasonic Corporation, Osaka (JP)

(72) Inventors: Naoya Sotani, Osaka (JP); Shinya Tsumura, Osaka (JP); Yukihiro Yoshimine, Osaka (JP)

(73) Assignee: Panasonic Corporation, Osaka (JP)

(21) Appl. No.: 17/004,511

(22) Filed: Aug. 27, 2020

(30) Foreign Application Priority Data
Aug. 28, 2019 (JP) 2019-155454

(51) Int. Cl. H01L 31/18; H01L 31/048

(52) U.S. Cl. CPC H01L 31/18; H01L 31/048

(57) ABSTRACT

A manufacturing method of a solar cell module according to an embodiment of the present disclosure includes a laminating process. The laminating process includes bringing a stack of overlapped elements of a solar cell module into a chamber, setting the stack on a hot plate, and heating the stack while pressing the stack with a pressing member. In the laminating process, the temperature of the pressing member is controlled by maintaining at least an entire contact portion of the pressing member, which is to be in contact with the stack, in contact with the upper chamber or the hot plate, or out of contact with the upper chamber and the hot plate. The temperature control is performed in a stand-by state before the stack is brought into the chamber.

### CROSS REFERENCE TO RELATED APPLICATION

This application claims priority to Japanese Patent Application No. 2019-155454 filed on Aug. 28, 2019, which is incorporated herein by reference in its entirety including the specification, claims, drawings, and abstract.

### TECHNICAL FIELD

The present disclosure relates to a manufacturing method of a solar cell module, in particular, a manufacturing method of a solar cell module including a laminating process.

### BACKGROUND

In general, a solar cell module includes a string of solar cells in which multiple solar cells are wired; two support substrates sandwiching the string of solar cells; and encapsulants. The encapsulants fill the space between the string of solar cells and the respective support substrates to encapsulate the solar cells. For example, Japanese Unexamined Patent Application Publication No. 2013-118321 discloses a manufacturing method of a solar cell module. The method includes a laminating process to bond, by thermocompression, a glass substrate, a resin sheet of a first encapsulant material, a string of solar cells, another resin sheet of a second encapsulant material, and a back sheet. These elements of the solar cell module are overlapped in this order from the light receiving surface of the module. In this laminating process, a stack of the overlapped elements of the solar cell module is compressed using a pressing member of elastic rubber.

### SUMMARY

In the above laminating process, in order to prevent, for example, the second encapsulant from overflowing to the light receiving surface side of the solar cell while maintaining a sufficient bonding force between the encapsulants and the support substrates, the temperature of the stack must be controlled such that uniform heating at a predetermined temperature is applied to the stack. However, because the temperature of the compressing member which compresses the stack may vary, the stack may not be uniformly heated, resulting in non-uniform quality of the manufactured products.

An object of the present embodiment is to provide a manufacturing method of a solar cell module which reduces variations of the temperature applied to a stack/stacks and enables uniform temperature heating to be applied to the stack/stacks in a laminating process.

A manufacturing method of a solar cell module according to one aspect of the present disclosure includes a laminating process which includes bringing a stack of overlapped elements of a solar cell module into a chamber. The chamber includes an upper chamber with a pressing member and a lower chamber with a hot plate. The laminating process also includes setting the stack on the hot plate. The laminating process further includes heating the stack while pressing the stack with the pressing member. In the laminating process, the temperature of the pressing member is controlled in a stand-by state before the stack is brought into the chamber. The control is performed by keeping at least an entire contact portion of the pressing member, which is to be in contact with the stack, in contact with the upper chamber or the hot plate, or out of contact with the upper chamber and the hot plate.

According to a manufacturing method of a solar cell module of the present disclosure, as variations in the temperature applied to the stack/stacks can be reduced in the laminating process, the stacks can be uniformly heated. As a result, solar cell modules of high quality can be reliably manufactured.

### BRIEF DESCRIPTION OF THE DRAWINGS

The figures depict one or more implementations in accordance with the present teaching, by way of example only, not by way of limitations. In the figures, like reference numerals refer to the same or similar elements. Embodiments of the present disclosure will be described based on the following figures, wherein:

FIG. 1 shows a cross sectional view of a solar cell module according to an embodiment of the present disclosure;

FIG. 2 shows a configuration of a laminating device used to manufacture the solar cell module, according to the embodiment of the present disclosure;

FIG. 3 shows a laminating process according to the embodiment of the present disclosure;

FIG. 4 shows a pressure P which is applied to a stack to be laminated, a temperature T of the stack, and a loss modulus G2 of an encapsulant in the laminating process according to the embodiment of the present disclosure;

FIG. 5 shows a laminating process according to another embodiment of the present disclosure;

FIG. 6 shows a laminating process according to yet another embodiment of the present disclosure; and

FIG. 7 shows a laminating process which is used to describe a background art.

### DETAILED DESCRIPTION

Manufacturing methods of a solar cell module according to embodiments of the present disclosure are described in detail below with reference to the attached drawings. The embodiments described below are merely examples. The manufacturing methods according to the present disclosure should not be limited to those embodiments. The drawings which are referred to in the description of the embodiments are schematically illustrated. Specifics, such as dimensional ratios between the elements illustrated in the drawings, should be determined based on the description below.

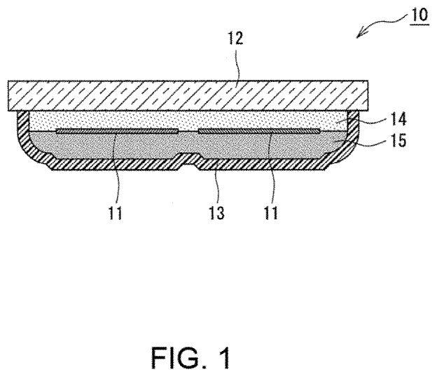

FIG. 1 shows a cross sectional view of a solar cell module 10 according to an embodiment of the present disclosure. As exemplarily shown in FIG. 1, the solar cell module 10 includes solar cells 11, a glass substrate 12 (first support substrate) which covers the light receiving surfaces of the solar cells 11, and a back sheet 13 (second support substrate) which covers the back surfaces of the solar cells 11. Alternatively, the first support substrate which is disposed on the light receiving surface side of the solar cells 11 may be a resin substrate, whereas the second support substrate which is disposed on the back surface side of the solar cells 11 may be a glass substrate. Although the solar cell module 10 has a rectangular shape in a plan view, the shape may be changed as required, for example, to a square or a pentagon.

It should be noted that the “light receiving surface” of the solar cell 11 is a surface through which light mainly enters, whereas the “back surface” is the surface on the side opposite the light receiving surface. Among light entering into the solar cell 11, over 50% (for example, over 80% or 90%) of the light enters from the light receiving surface side. The terms, “light receiving surface” and “back surface” are used for the solar cell module 10 and also for a photoelectric converter described blow.

The solar cell module 10 includes a first encapsulant 14 which fills a gap between the solar cells 11 and the glass substrate 12, and a second encapsulant 15 which fills a gap between the solar cells 11 and the back sheet 13. The solar cells 11 are sandwiched between the glass substrate 12 and the back sheet 13, and encapsulated by the first encapsulant 14 and the second encapsulant 15. Although two solar cells 11 are exemplarily shown in FIG. 1, the number of solar cells 11 included in the solar cell module 10 is not limited to any number. The solar cell module 10 generally includes multiple solar cells 11. Adjacent solar cells 11 are wired with each other in series (wiring not shown), forming a string of the solar cells 11.

Each solar cell 11 includes a photoelectric converter which generates carriers by receiving sunlight, and a collector electrode which collects carriers. The photoelectric converter has a substantially square shape in a plan view, with four diagonally cut corners. As an example, the photoelectric converter includes a semiconductor substrate of crystalline silicon (Si), gallium arsenide (GaAs), indium phosphide (InP), and a transparent conductive layer deposited on an amorphous semiconductor layer or a doped layer (formed by thermal diffusion or other process) deposited on the semiconductor substrate.

The collector electrode includes, for example, a light receiving surface electrode deposited on a light receiving surface of the photoelectric converter, and a back surface electrode deposited on a back surface of the photoelectric converter. The collector electrode may include multiple narrow, elongated finger electrodes, which are arranged in parallel to each other. The collector electrode may also include a busbar electrode which is wider than the finger electrode and arranged substantially perpendicular to the finger electrodes. The back surface electrode may cover substantially the entire back surface of the photoelectric converter.

The glass substrate 12 may cover the entire string of the solar cells 11 to protect the solar cells 11 from external impact, humidity, or other factors. The total luminous transmittance of the glass substrate 12 may be high, for example, 80% to 100%, or 85% to 95%. The total luminous transmittance is measured as defined in Japanese Industrial Standards (JIS) K7361-1 (Plastics—Determination of the total luminous transmittance of transparent materials—Part 1: Single beam instrument).

The back sheet 13 may be a translucent substrate, similarly to the glass substrate 12, or an opaque substrate. The total luminous transmittance of the back sheet 13 is not limited to any particular value, and may be 0%. In order to, for example, reduce the weight of the module, a resin sheet thinner than the glass substrate 12 is used for the back sheet 13.

For the first encapsulant 14 and the second encapsulant 15, resin which can be softened or melted in the laminating process described below is mainly used. Each encapsulant may include an antioxidant, a UV absorber, and so forth. The first encapsulant 14 is made of colorless, transparent resin which has a high total luminous transmittance. The second encapsulant 15 in contrast may contain a colorant such as a white pigment. The white pigment such as titanium oxide can increase incident light of the solar cell 11 by reflecting sunlight.

The first encapsulant may be made of resin, for example, polyolefin which can be obtained by polymerizing at least one substance which is selected from ethylene and α-olefin of carbon number 3 to 20 (for example, polyethylene, polypropylene, a random or block copolymer of ethylene and α-olefin); polyester; polyurethane; epoxy resin; and a copolymer of ethylene and vinyl carboxylate, acrylic ester, or other vinyl monomer (for example, ethylene-vinyl acetate copolymer).

The first encapsulant 14 may contain thermosetting resin which is crosslink resin containing a crosslink component, a crosslink agent, or other crosslink substance whose crosslinking reaction advances by being heated. The most preferable resin for the first encapsulant 14 may be crosslinkable polyolefin (POE). Use of POE for the first encapsulant 14 achieves a good encapsulation, improving reliability of the solar cell module 10.

A crosslinking start temperature of the first encapsulant 14 is for example, 135° C. to 140° C., or may be higher than 140° C. In the present embodiment, the crosslinking start temperature is a temperature at which a loss tangent (tanδ=G2/G1, where G1 is storage modulus, and G2 is loss modulus) obtained with a curing torque defined in Japanese Industrial Standards (TIS) K6300-2 falls below 1 in about 10 minutes.

Although the second encapsulant 15 may be made of the same resin as the first encapsulant 14, it is more preferable to use resin that is different from that of the first encapsulant 14. The second encapsulant 15 may contain thermosetting resin. Particularly preferable resin for the second encapsulant 15 is a crosslinkable ethylene-vinyl acetate copolymer (hereinafter referred to as “EVA”). EVA contains, as a crosslinking agent, organic peroxide such as benzoyl peroxide, dicumyl peroxide, 2,5-dimethyl-2,5-di (t-butyl peroxy) hexane.

The crosslinking start temperature of the second encapsulant 15 may be lower than that of the first encapsulant 14, and may be for example, 120° C. to 130° C. Although the viscosity of each encapsulant while being heated in the laminating process is not limited to a particular range, in general, when using the above mentioned materials for the encapsulants, the viscosity of the second encapsulant 15 before the start of curing is higher than that of the first encapsulant 14 before the start of curing. The first encapsulant 14 and the second encapsulant 15 flow, for example, in the laminating process, and the liquidity of the first encapsulant 14 is higher than that of the second encapsulant 15.

The first encapsulant 14 and the second encapsulant 15 may include a coupling agent. The use of the coupling agent increases a bonding force of the encapsulants to the solar cells 11, the glass substrate 12, and the back sheet 13, facilitating reduction of interface peel off. Examples of the coupling agents include silane coupling agents, titanate coupling agents, and aluminate coupling agents. Of these coupling agents, the silane coupling agents are most preferable. Examples of the silane coupling agents include vinyltriethoxyxysilane, γ-glycidoxypropyltrimethoxysilane, and γ-methacryloxypropyltrimethoxysilane.

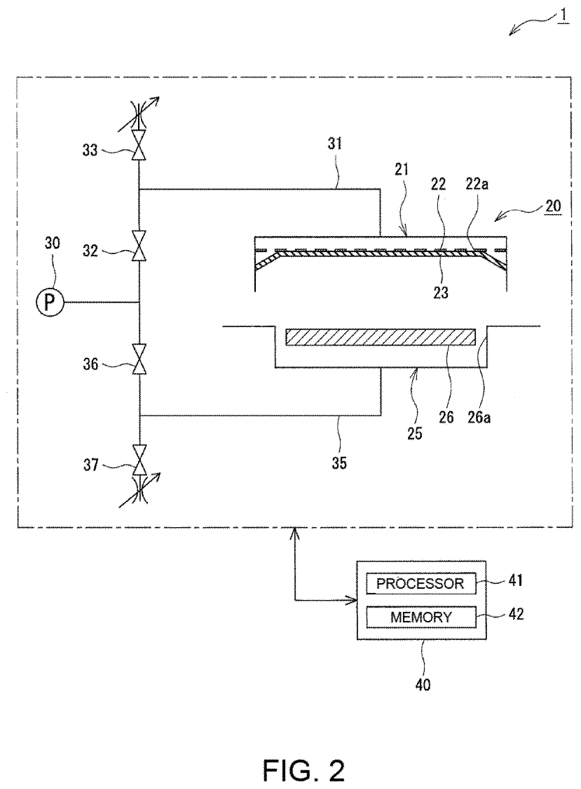

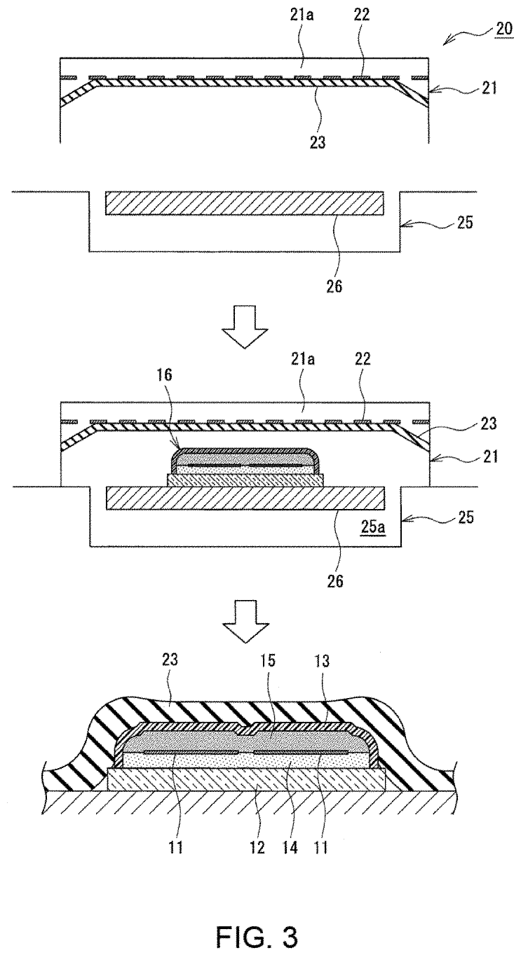

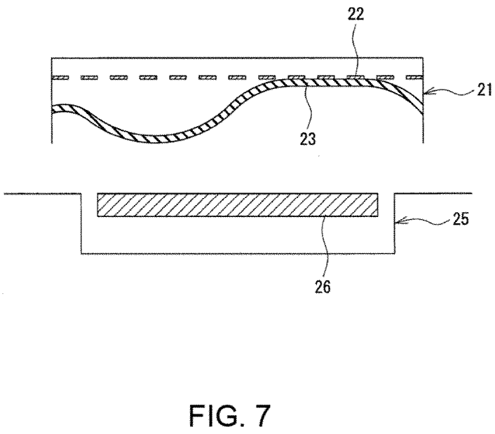

The manufacturing method of the solar cell module 10 is described in detail below with reference to FIGS. 2 to 6. FIG. 2 exemplarily shows a configuration of a laminating device 1 according to an embodiment of the present disclosure; FIG. 3 exemplarily shows a laminating process of the solar cell module 10 according to the embodiment of the present disclosure; and FIG. 7 shows a laminating process of a background art for comparison.

The manufacturing method of the solar cell module 10 includes a laminating process. The solar cell module 10 is manufactured by a method including a laminating process which is exemplarily shown in FIG. 3. In the laminating process, a stack 16 (multilayered structure) of overlapped elements from which the solar cell module is formed is bonded by thermocompression bonding using the laminating device 1 which is exemplarily shown in FIG. 2.

The manufacturing process of the solar cell module 10 may include a curing process in which a further heat treatment is applied to the stack 16 which has been bonded by thermocompression in the laminating process. In the curing process, the stack 16 may be heated at a higher temperature or for a longer time than in the laminating process, to advance the crosslinking reaction of the encapsulants and reaction of the silane coupling agent. A heating furnace to perform the curing process is not limited to any type as long as the stacks 16 can be disposed inside the heating furnace. For example, a resistance heating furnace can be used.

As exemplarily shown in FIG. 2, the laminating device 1 includes a chamber 20 in which thermocompression bonding is applied to the stacks 16, a vacuum pump 30 which evacuates the chamber 20, and a controller 40 which controls the chamber 20 and the vacuum pump 30. The chamber 20 includes an upper chamber 21 and a lower chamber 25. The chamber 20 is structured such that the internal space is opened or closed by moving the upper chamber 21 up or down. The internal space of the chamber 20 is a vacuum chamber which can be evacuated by the vacuum pump 30. A first pipe 31 leading to the vacuum pump 30 is connected to the upper chamber 21, whereas a second pipe 35 also leading to the vacuum pump 30 is connected to the lower chamber 25.

The upper chamber 21 includes a top face portion and a side face portion and is opened downward. The inner space of the chamber 20 is sealed by moving the upper chamber 21 downward to be in contact with the upper surface of the lower chamber 25. The upper chamber 21 includes a metal plate 22 with air perforations 22a formed therein and a pressing member 23 which compresses the stack 16. The metal plate 22 and the pressing member 23 are respectively attached to, for example, the side face portion of the upper chamber 21. The metal plate 22 is, for example, a punching metal which prevents the pressing member 23 from being attached over the inlet of the first pipe 31. The temperature of the metal plate 22 is, for example, 30° C. to 70° C. (higher than a room temperature but lower than a hot plate 26).

The pressing member 23 is attached inside the upper chamber 21 at a position lower than the metal plate 22 and closes the opening of the upper chamber 21. In this way, the pressing member 23 partitions the inner space of the chamber 20 into an upper zone 21a and a lower zone 25a. The lower zone 25a is defined when the upper chamber 21 is moved downward to close the chamber 20. The stack 16 is disposed in the lower zone 25a. The pressing member 23 may be made of heat resistant rubber such as elastic silicone rubber. The pressing member 23 presses the stacks 16 from upper side (by pressing pressure applied inside of the upper zone 21a). The pressing member 23 is generally called a “diaphragm”.

The lower chamber 25 includes a heater with the hot plate 26. In the embodiment shown in FIG. 2, air perforations 26a are formed around the hot plate 26. The hot plate 26 has a large enough size to dispose a single or multiple stacks 16 thereon. The stacks 16 are disposed on the upper surface of the hot plate 26 in the chamber 20. The temperature of the hot plate 26 is set to, for example, a temperature higher than the crosslinking start temperature of the first encapsulant 14, or higher than the crosslinking start temperature of the second encapsulant 15 (for example, 140° C. to 170° C.).

As described above, the laminating device 1 includes the first pipe 31 and the second pipe 35. A first open/closed valve 32 and a first leak valve 33 are provided at the first pipe 31, whereas a second open/closed valve 36 and a second leak valve 37 are provided at the second pipe 35. The upper zone 21a is evacuated, for example, by running the vacuum pump 30 and opening the first open/closed valve 32. After closing the first open/closed valve 32 with the upper zone 21a in vacuum, the degree of vacuum in the upper zone 21a can be controlled or the upper zone 21a can be returned to be at atmospheric pressure by adjusting the first leak valve 33. Similarly, the degree of vacuum in the lower zone 25a can be controlled by adjusting the second open/closed valve 36 and the second leak valve 37.

The controller 40 controls an up/down mechanism of the upper chamber 21, the heater of the lower chamber 25, the vacuum pump 30, and the above valves. The controller 40 is configured with a computer which includes a processor 41, a memory 42, an input/output interface, and other components. The processor 41 may be a CPU or GPU which performs the manufacturing method described below by reading out and performing control programs. The memory 42 may include a non-volatile memory, such as a ROM, HDD, and SSD, and a volatile memory, such as a RAM. The control programs are stored in the non-volatile memory.

As exemplarily shown in FIG. 3, the laminating process includes bringing the stack 16 into the chamber 20 including the upper chamber 21 in which the pressing member 23 is disposed and the lower chamber 25 in which the hot plate 26 is disposed. The laminating process also includes setting the stack 16 on the hot plate 26, and heating the stack 16 while pressing with the pressing member 23. The stack 16 is configured to include the glass substrate 12, the first encapsulant 14, a string of the solar cells 11, the second encapsulant 15, and the back sheet 13, in this order from the hot plate 26 side.

In the laminating process, after the stack 16 is brought into the chamber 20, the upper chamber 21 is closed, and the stack 16 is thermocompressed with the pressing member 23. Then, the upper chamber 21 is opened again and the stack 16 is removed from the chamber 20. After the processed stack 16 is removed from the chamber 20, the next stack 16 is brought into the chamber 20. The laminating process continues in such an intermittent manner, i.e. batch operation.

In the laminating process exemplarily shown in FIG. 3, in a stand-by state before the stack 16 is brought into the chamber 20, the temperature of the pressing member 23 is controlled. The temperature control of the pressing member 23 is performed by bringing at least the entire contact portion of the pressing member 23, which is to be in contact with the stack 16 (hereinafter referred to as “contact portion”), into contact with the upper chamber 21. More specifically, the entire contact portion of the pressing member 23 is brought into contact with the metal plate 22 of the upper chamber 21. As described in more detail below, the temperature control of the pressing member 23 may be started before removing the already-pressed stack 16 from the chamber 20. Although the chamber 20 in the stand-by state exemplarily shown in FIG. 3 is opened, the chamber 20 may be closed.

In general, the pressing member 23 is cooled by the metal plate 22 by bringing the pressing member 23 into contact with the metal plate 22. The pressing member 23 comes into contact with the hot plate 26 indirectly via the stack 16 or partially directly. Accordingly, the temperature of the pressing member 23 is higher than the metal plate 22 when the laminate processing continues. Because the temperature of the metal plate 22 which is not in contact with the hot plate 26 is, for example, 30° C. to 70° C., the temperature of the portion of the pressing member 23 in contact with the metal plate 22 is cooled down to this temperature of the metal plate 22.

In other words, in the laminating process according to the present embodiment, the temperature of the pressing member 23 is controlled to be uniformly within small range/a certain range by contact with the metal plate 22 in the stand-by state. As a result, because uniform heating can be applied to the stack/stacks 16, solar cell modules 10 of high quality can be reliably manufactured. The laminating device 1 may further include a temperature adjusting device which maintains the metal plate 22 at a predetermined temperature. In that case, the pressing member 23 may be cooled or heated to the predetermined temperature.

As exemplarily shown in FIG. 7, in a laminating process in a background art, temperature control of the pressing member 23 in the stand-by state is not performed. For example, because only a portion of the pressing member 23 is in contact with the upper chamber 21 (specifically, the metal plate 22), the temperature of the pressing member 23 may vary at different points of the pressing member 23. As a result, the stack 16 cannot be heated at a uniform temperature, causing non-uniform quality of the product. Further, temperature variations may occur between the stacks 16 in the respective laminating processes, resulting in non-uniform quality of the products.

In a background art, in order to release the compressing force, after pressing the stack 16 with the pressing member 23 for a predetermined period of time, the lower zone 25a is simply opened to atmospheric pressure. In this step, because the exhaust valve (the first open/closed valve 32) and the first leak valve 33 of the upper zone 21a are closed, a certain amount of air (the applied pressure x the volume of the upper zone when the pressure is applied) is maintained in the sealed space. When the external side of the pressing member 23 is exposed to atmospheric pressure, the pressing member 23 is pushed upward such that the pressure of the upper zone 21a becomes substantially equal to the atmospheric pressure. Accordingly, the position of the pressing member 23 becomes unstable such that the pressing member 23 partially comes into contact with the upper chamber 21 (the metal plate 22) and the temperature of the portion of the pressing member 23 in contact with the upper chamber 21 drops significantly. Such partial contact of the pressing member 23 with the upper chamber 21 (the metal plate 22) may also occur when the chamber 20 is closed and the upper zone 21a is evacuated in the next laminating process. In either case, temperature variations at different points of the pressing member 23 may occur. In order to reduce such temperature variations, the temperature of the contact portion of the pressing member 23 can be controlled by setting the entire contact portion of the pressing member 23 in contact with the upper chamber 21 (the metal plate 22) or the hot plate 26, or out of contact with the upper chamber 21 (the metal plate 22) and the hot plate 26.

As a method to set the entire contact portion of the pressing member 23 in contact with the metal plate 22, for example, the upper zone 21a may be evacuated to a degree of vacuum which is sufficient to set the entire contact portion of the pressing member 23 in contact with the metal plate 22 by running the vacuum pump 30 and opening the first open/closed valve 32. As a specific example, the first open/closed valve 32 may be opened, while running the vacuum pump 30. In the stand-by state, because the external side of the pressing member 23 is exposed to atmospheric pressure, substantially the entire contact portion of the pressing member 23 may be in contact with the metal plate 22 and the side face portion of the upper chamber 21.

In the laminating process according to the present embodiment, in a stand-by state, at least the entire contact portion of the pressing member 23 may be set in contact with the upper chamber (the metal plate 22). Then, the pressing member 23 may be set in contact with the hot plate 26 for more than a predetermined period of time before bringing the stack 16 into the chamber 20. In this step, at least the entire contact portion of the pressing member 23 should be set in contact with the hot plate 26. An example of the predetermined period of time is 5 to 60 seconds.

By bringing the pressing member 23 in contact with the hot plate 26, the pressing member 23 with uniform or none uniform temperature can be heated up the uniform temperature. In this way, the stack can be more uniformly heated. As a method to set the entire contact portion of the pressing member 23 in contact with the hot plate 26, for example, the chamber 20 may be closed, the pressure in the upper zone 21a may be returned to atmospheric pressure, and the lower zone 25a may be evacuated.

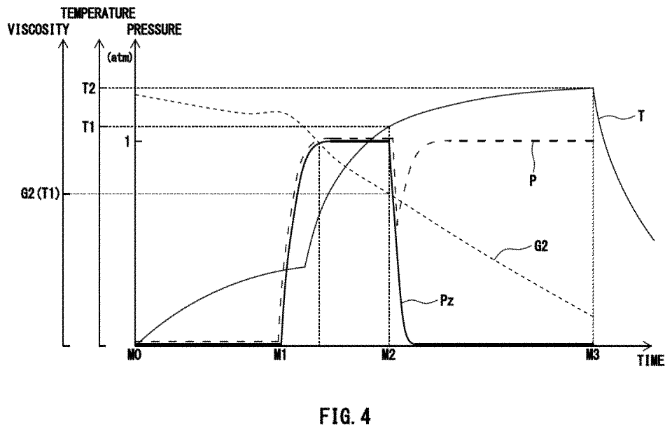

FIG. 4 is a diagram showing pressure P applied to the stack 16, temperature T of the stack 16, and loss modulus G2 of the first encapsulant 14 at certain points after the stack 16 is brought into the chamber 20 until removal. The pressure Pz is a pressure applied by the pressing member 23 to the stack 16. Temperature T of the stack 16 is measured with a thermocouple attached to internal surfaces of the glass substrate 12 and the back sheet 13, and averaging the measured values obtained by the thermocouple.

In the laminating process, after the stack 16 is brought into the chamber 20 and set on the upper surface of the hot plate 26, the elements in the stack 16 are bonded by thermocompressing the stack 16 with the pressing member 23 whose temperature has been controlled in the stand-by state. The first encapsulant 14 and the second encapsulant 15 which are generally provided in the form of resin sheets are heated via the glass substrate 12 which is heated by the heat from the hot plate 26 to be softened or melted.

As exemplarily shown in FIG. 4, in the laminating process, after heating the stack 16 for a predetermined period of time (M0 to M1) while evacuating the upper zone 21a and the lower zone 25a, pressing with the pressing member 23 is started (M1). The predetermined period of time (M0 to M1) is, for example, 10 to 90 seconds. In the laminating process exemplarily shown in FIG. 3, the entire contact portion of the pressing member 23 may be disposed in contact with the upper chamber 21 (the metal plate 22) for the predetermined period of time (M0 to M1). Prior to M0, the entire contact portion of the pressing member 23 has been in contact with the upper chamber 21 (the metal plate 22a) to be uniformed its temperature, which is maintained until M1, since no contacted with other members.

Pressure Pz applied with the pressing member 23 is, for example, 1.0 atm at maximum (for example, 0.6 to 1.0 atm). The laminating device may have a pressing mechanism which can apply a pressure over 1.0 atm. Temperature T of the stack 16 significantly increases by being firmly pressed against the hot plate 26. As the temperature of the stack 16 rises, loss modulus G2 of the encapsulants significantly decreases.

The change in loss modulus G2 along with the temperature change of the respective encapsulants shows the same tendency as the change in viscosity of the encapsulants. For a viscoelastic element, complex modulus G*(G*=G1+iG2, i²=−1) is used instead of elastic modulus E of elastic element. Loss modulus G2 is a measure of the energy dissipated as heat when being deformed, and can be used as an index showing viscosity. In the present disclosure, loss modulus G2 of the encapsulants is obtained using a dynamic viscoelastic measurement (dynamic mechanical analysis (DMA), refer to Journal of Network Polymer, Japan, published by Japan Thermosetting Plastics Industry Association, Vol. 32, No. 6 (2011), p. 362).

The DMA measurement conditions are as follows:

Frequency: 10 Hz

Heating rate: 10° C./min (−50° C. to 150° C.)

Deformation mode: Pulling

In the laminating process, the pressing with the pressing member 23 is stopped (M2) at a temperature T1 at which the first encapsulant 14 or the second encapsulant 15 maintains a predetermined loss modulus G2 (T1). The pressing with the pressing member 23 can be stopped by bringing the lower zone 25a to atmospheric pressure and the upper zone 21a to atmospheric pressure or lower. The stack 16 is uniformly pressed at the hydrostatic pressure by the atmospheric pressure in a temperature range at which loss modulus G2 is below a predetermined loss modulus G2 (T1). This significantly reduces the likelihood of the second encapsulant 15 overflowing to the light receiving surface side of the solar cell 11. The pressing period of time (M1 to M2) is significantly shorter than that of a background art laminating process, for example, 90 seconds or less.

In this step, in order to prepare for the laminating process of the next stack 16, the entire contact portion of the pressing member 23 may be set completely in contact with the metal plate 22 (or set completely out of contact). In this way, after stopping the pressing with the pressing member 23, the temperature control of the pressing member 23 can be started before removing the pressing-applied stack 16 from the chamber 20. In the laminating process exemplarily shown in FIG. 3, the temperature of the pressing member 23 is controlled. The control is performed by maintaining the entire contact portion of the pressing member 23 in contact (or out of contact) with the upper chamber 21 (the metal plate 22). This continues, for example, for a period of time from the stop (M2) of the pressing with the pressing member 23 to the beginning of the evacuation time M0 of the next laminating process, it should be longer than the predetermined period (if not, it must be complimented by elongation of standby state).

After the stop of the pressing with the pressing member 23, the heating of the stack 16 may be continued until the temperature of the stack 16 reaches one of the crosslinking start temperatures of the first encapsulant 14 or the second encapsulant 15 which is higher than the other. When the crosslinking start temperature of the first encapsulant 14 is higher than that of the second encapsulant 15, the heating may continue until temperature T of the stack 16 reaches at least the crosslinking start temperature T2 of the first encapsulant 14 (M3) after the pressing with the pressing member 23 is stopped. In this step, because the stack 16 is pressed at the hydrostatic pressure by the atmospheric pressure, the bonding of each encapsulant to the solar cell 11 and other elements is further strengthened.

Loss modulus G2 (T1) of the first encapsulant 14 or that of the of the second encapsulant 15 which is used as a threshold to stop the pressing with the pressing member 23 may be set to 10³ Pa or higher, for example, in a range of 10³ Pa to 10⁶ Pa. In the laminating process, the pressing with the pressing member 23 may be stopped when the temperature of the stack 16 reaches 80° C. to 110° C. or 85° C. to 105° C. Because the loss modulus of the encapsulants used for the solar cell module 10 is generally lower than 10³ Pa at around 110° C., the overflowing of the second encapsulant 15 can be reduced by stopping the pressing with the pressing member 23 using 110° C. as the threshold.

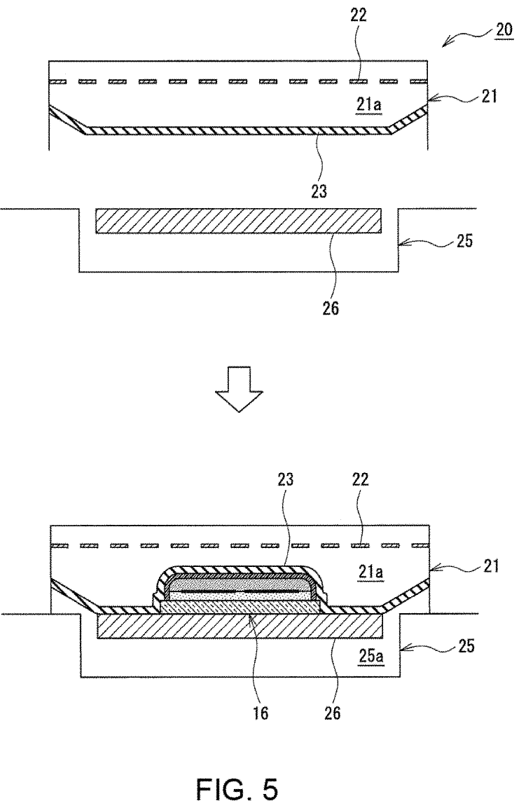

In the laminating process exemplarily shown in FIG. 5, in the stand-by state before the stack 16 is brought into the chamber 20, the entire contact portion of the pressing member 23 is set out of contact with the upper chamber 21 and the hot plate 26. Because, in general, the laminating process continues intermittently, the temperature of the pressing member 23 when the pressing is stopped (M2) is, for example, temperature T1. Without contact with the upper chamber 21 (the metal plate 22), the temperature of the pressing member 23 may be maintained for a certain period of time. Specifically, the temperature of the pressing member 23 can be controlled to be around T1. Variations of the temperature at different points of the pressing member 23 can be reduced, for example, by arranging the entire contact portion of the pressing member 23 to be out of contact with the metal plate 22. Similarly to the process shown in FIG. 3, in the process exemplarily shown in FIG. 5, the stack 16 is brought into the chamber 20 and set on the upper surface of the hot plate 26, and compressed with the pressing member 23 whose temperature has been controlled in the stand-by state.

As an example of a method to maintain the entire contact portion of the pressing member 23 out of contact with the upper chamber 21 and the hot plate 26, the difference in pressure between the upper zone 21a and the external side of the pressing member 23 should be maintained to be almost zero. For example, the pressure in the upper zone 21a and the lower zone 25a may be equal to the atmospheric pressure. In the embodiment shown in FIG. 5, substantially the entire contact potion of the pressing member 23 may be maintained out of contact with the metal plate 22 and the hot plate 26, excluding the portions attached to the side face portion of the upper chamber 21.

In the laminating process exemplarily shown in FIG. 5, in the stand-by state, at least the entire contact portion of the pressing member 23 may be maintained out of contact with the upper chamber 21 and the hot plate 26. Then, the stack 16 may be brought into the chamber 20 after maintaining the pressing member 23 in contact with the hot plate 26 for a predetermined period of time. During this step, at least the entire contact portion should be maintained in contact with the hot plate 26. The predetermined period of time is, for example, 5 to 60 seconds. Of course, during evacuating process until beginning of the compression process, the difference in pressure between the upper zone 21a and the external side of the pressing member 23 should be maintained to be almost zero.

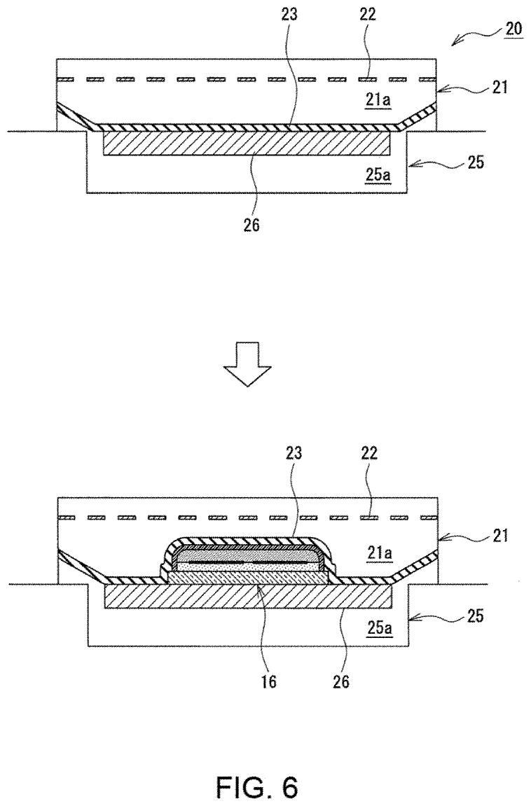

In the laminating process exemplarily shown in FIG. 6, the temperature of the pressing member 23 is controlled by bringing the entire contact portion of the pressing member 23 into contact with the hot plate 26 in the stand-by state, more preferably immediately before, the stack 16 is brought into the chamber 20. Because the pressing member 23 is maintained away from the hot plate 26, for example, in a period after the stop of the pressing of the stack 16 and before the compression of the next stack 16, the temperature of the pressing member 23 is lower than the hot plate 26. The temperature of the pressing member 23 may be lower in a case where the pressing member 23 has been in contact with the metal plate 22. The temperature of the pressing member 23 increases by bringing the pressing member 23 into contact with the hot plate 26.

The temperature of the hot plate 26 is generally maintained to be constant. Accordingly, in the laminating process exemplarily shown in FIG. 6, the temperature of the pressing member 23 is controlled to be uniform using the hot plate 26 in the stand-by state. Similarly to the processes exemplarily shown in FIGS. 3 and 5, in the process exemplarily shown in FIG. 6, the stack 16 is brought into the chamber 20 and set on the upper surface of the hot plate 26, and then, compressed with the pressing member 23 whose temperature has been controlled in the stand-by state. Of course, during evacuating process until beginning of the compression process, the difference in pressure between the upper zone 21a and the external side of the pressing member 23 should be maintained to be almost zero.

As an example of a method to bring the entire contact portion of the pressing member 23 into contact with the hot plate 26, the lower zone 25a may be evacuated with the chamber 20 closed and the upper zone 21a at atmospheric pressure. Specifically, this example method can be achieved by running the vacuum pump 30, opening the second open/closed valve 36, closing the first open/closed valve 32, and fully opening the first leak valve 33. In the laminating process exemplarily shown in FIG. 6, the chamber 20 must be opened once to bring the stack 16 into the chamber 20. During this step, because the upper zone 21a is maintained at the atmospheric pressure, the pressing member 23 does not come into contact with the upper chamber 21 (the metal plate 22).

In the laminating process exemplarily shown in FIG. 6, after the pressing of the stack 16 is stopped, the entire contact portion of the pressing member 23 may be maintained in contact with the upper chamber 21 until the processed stack 16 is removed. After the processed stack 16 is removed, the chamber 20 is closed and the entire contact portion of the pressing member 23 is brought into contact with the hot plate 26. The period of time to maintain the pressing member 23 in contact with the hot plate 26 is, for example, 10 to 120 seconds. While the method shown in FIG. 6 can provide the highest controllability of the temperature, the processed stacks 16 cannot be brought into or removed from the chamber 20 at the same time. This increases the number of times the chamber 20 is opened and closed, causing a disadvantage of longer processing time.

As described above, according to the above manufacturing method, temperature variations of the pressing member 23 in the laminating process can be reduced during the stand-by state. As a result, because the temperature variations of the stack/stacks 16 can be reduced, the solar cell modules 10 of high quality can be reliably manufactured.

Various modifications are possible to the above described embodiments without departing from the scope of the invention. For example, although the pressing with the pressing member 23 is stopped at a temperature at which the loss modulus of the first encapsulant is maintained equal to or over 10³ Pa in the laminating process exemplarily described in the above embodiments, the pressing with the pressing member 23 may be continued to a higher temperature.

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

1. A manufacturing method of a solar cell module, comprising:
a laminating process which comprises
bringing a stack of overlapped elements of a solar cell module into a chamber which comprises an upper chamber with a pressing member and a lower chamber with a hot plate, and setting the stack on the hot plate; and
heating the stack while pressing the stack with the pressing member,
wherein, in the laminating process, the temperature of the pressing member is controlled by maintaining at least an entire contact portion of the pressing member, which is to be in contact with the stack, in contact with the upper chamber or the hot plate, or out of contact with the upper chamber and the hot plate, in a stand-by state before the stack is brought into the chamber.

2. The manufacturing method of the solar cell module according to claim 1, wherein, in the laminating process, the temperature of the pressing member is controlled in the stand-by state by maintaining at least the entire contact portion of the pressing member which is to be in contact with the stack in contact with the upper chamber or the hot plate.

3. The manufacturing method of the solar cell module according to claim 1, wherein, in the stand-by state in the laminating process, at least the entire contact portion of the pressing member which is to be in contact with the stack is maintained in contact with the upper chamber or out of contact with the upper chamber and the hot plate, and then, the stack is brought into the chamber after the entire contact portion of the pressing member which is to be in contact with the stack is maintained in contact with the hot plate for a certain period of time.

4. The manufacturing method of the solar cell module according to claim 1, wherein, in the stand-by state in the laminating process, at least the entire contact portion of the pressing member which is to be in contact with the stack is maintained in contact with the upper chamber, and then, the stack is brought into the chamber after the entire contact portion of the pressing member which is to be in contact with the stack is maintained in contact with the hot plate for a certain period of time.
